(19) United States
(12) Patent Application Publication
(10) Pub. No.: US 2010/0097777 A1
(43) Pub. Date: Apr. 22, 2010

(54) Symbiotic Containment Enclosure

(76) Inventor: John Mecca, Kings Park, NY (US)

Correspondence Address: JOHN MECCA, 119 WHITTIER DRIVE, KINGS PARKS, NY, 11754, US

(21) Appl. No.: 12/426,510

(22) Filed: Apr. 20, 2009

Related U.S. Application Data
(63) Continuation-in-part of application No. 11/758,760, filed on Jun. 6, 2007, now Pat. No. 7,541,885.

(51) Int. Cl. H05K 5/02; H04B 1/03

(52) U.S. Cl. 361/814

(57) ABSTRACT

A package for, interacting symbiotically, integrally and exclusively with and for patent application number 11758760 electromagnetic circuit. Such package is comprised of one or more layers of materials moderating the circuits electromagnetic field within. Such a package has proximal inductors that are electromagnetic conduits for input and output of electromagnetic energy terminating proximally in relation to the circuit within.

### BACKGROUND OF THE INVENTION

The present innovation as a continuation-in-part of application 11758760 Class-Subclass 331-187000, is titled “Symbiotic Containment Enclosure” heretofore known by acronym (SCE); wherein the prior art inventions to date having prepackaging for broadband radio frequency coverage have no history of a circuit defined as application number 11758760 titled “An Infinite Radio Frequency Spectrum Transceiver heretofore known by acronym (IRFS)”; such that the prior art requiring such Symbiotic Containment Enclosure is exclusively then the IRFS circuit. Where symbiotic interrelation between the packaging (SCE) and the transceiver (IRFS) is addressed by the innovation of issue of SCE packaging. Prior art other than the IRFS is non-existent and therefore the SCE as it is as well, in a symbiotic referenced connection to the IRFS operation is new and unique, in its symbiotic relationship to the Infinite Radio Frequency Spectrum Transceiver. Prior art deals with substantially different approaches altogether where ultra broad band outputs or inputs are propounded to be the resultant. As a rule such prior art has the output or input of broadband organized in steps as opposed to the Infinite Radio Frequency Transceiver (IRFS) circuit which outputs and inputs the entire radio frequency spectrum. Where the originality and novelty of the IRFS exists where it is coupled to the packaging herein detailed as “SYMBIOTIC CONTAINMENT ENCLOSURE” (SCE), the relevant issue then is, that there is no prior art touching upon the same juxtaposition or utilization as outlined for the symbiont relationship here of the SCE.

Prior art of a somewhat but distant similarity as an aside has to do with suppression of fields by waveguides, absorbers and magnetic fields in support of moderating the path of passage of radio frequency energy commonly referred to as microwave mixers, dividers, up-converters and down-converters as such art relates to devices producing limited breadth of frequencies from some point on the electromagnetic radio spectrum to some other point on the radio spectrum, where such prior art has limitations as to any comparison to the SCE moderation of the IRFS. Specifically such techniques have as need be the need to be positioned in the traveling pathway of a stream of radio frequency energy for one issue and that they are nearly unrecognizable as means and methods as compared to the SCE symbiotic interrelation to the IRFS.

SCE packaging of IRFS devices creates by novelty, further differences from prior art as well as advantages if it can even be compared to prior art, in that there are unique properties being affected of electromagnetic spectrum energy in the IRFS SCE interface hitherto unknown where it regards the claims of the IRFS. The unique output and piggybacking of infinite frequencies has the elements of the IRFS SCE interface of their fields interfacing in coaction such that the unique properties of the piggy backing infinite frequencies imbued with special properties hitherto unknown in their action to exist as a resultant and by that their modification thorough symbiotic effects from the SCE are as well unique despite structural similarities of distantly related previous art. There is therefore no known relative art on record in similarity to the SCE packaging where it is entirely dedicated towards the IRFS.

1. Field of Invention

The symbiotic containment enclosure as an intrinsic complimentary adjunct to the Infinite Radio Frequency Spectrum Transceiver known as an IRFS circuit, heretofore the IRFS is unknown and therefore without any previous existence; where such symbiotic containment enclosure is part and parcel to advantageous and economical usage of an IRFS.

2. Brief Description of the State of Knowledge In the Art

Where the “symbiotic containment enclosure” (SCE) has to do with the physical encapsulation of the Infinite Radio Frequency Spectrum Transceiver (IRFS) circuit.

Where that encapsulation takes into consideration the field of radio frequency energy generated by the IRFS; such that the IRFS has a field energy that will induct some portion of it's energy into the surrounding area of it's operation and where such radiating energy may not be desired and an interest is in restricting such radiating of energy, a novel and unique approach to such an enclosure have been innovated here for encapsulation and or moderation of the electromagnetic energy of the IRFS circuit needs to be supplied.

As well where the issue of the unique properties of the SCE has advantage in the management of moderating electromagnetic spectrum energy fields on traditional microelectronic substrates or PC boards the IRFS modalities recited in part and or entirety where regarding such use is as can be operational as coverage for such overlapping of use of the present art as can be derived from the claims as outlined in this new innovation. The use thereof of the IRFS SCE XY interface exists, computerized means of input and output of frequencies to modulate the IRFS XY field for purposes of processing electromagnetic frequency energy for any desired resultant.

### OBJECTS AND SUMMARY OF THE INVENTION

Where the SCE encapsulation takes into consideration the field of electromagnetic spectrum radio frequency energy generated by the IRFS; such that the IRFS has a field energy at XY that will induct some portion of it's energy into the surrounding area of its operation; where encapsulation and moderation of that energy induced into the encapsulation is desired. A symbiotic containment enclosure being a methodology is presented that completely surrounds the IRFS circuit, moderating its field and also has accessory inductors that separately can be used to reactively moderate the IRFS field or be moderated by the IRFS field.

There exists therefore through the “symbiotic containment enclosure” in close proximity to the IRFS circuit field area of XY a unique symbiotic relationship where the electromagnetic radio frequency spectrum fields from the IRFS induce said fields into the encapsulating enclosure. Thereby the SCE moderates the IRFS field and the “symbiotic containment enclosure” as well has coaxial inductors separate from the IRFS circuit that are in proximity to the IRFS field XY and upon input or output of electromagnetic frequency energy communicating through such inductors do thereby moderate the IRFS circuit. Further moderation of the relationship of the SCE, IRFS and inductors is the use of a computer to moderate the coaxial electromagnetic radio frequency input and output of the coaxial leads in proximity to the IRFS XY field; subsequent moderation of the power supply being manipulated by computer control of said power supply voltage and amperage is accordingly an attribute of said moderation of the IRFS, SCE and proximal inductors.

### BRIEF DESCRIPTION OF THE DRAWINGS

In order to more fully understand the Objects Of Invention, the following Detailed Description of the Illustrative Embodiments should be read in conjunction with the appended figure drawings, wherein:”

FIG. 1 is a schematic representation of the circuit that resides within the symbiotic reactive encapsulating package, where such circuit electromagnetic field is to be moderated by the encapsulating walls of the SCE.

FIG. 2 is a view of the XY interface area of electromagnetic spectrum energy generally as it originates from the IRFS.

FIG. 3 is a view of the XY interface area of electromagnetic spectrum energy generally as it originates from the IRFS.

FIG. 4 is a view of the XY interface area of electromagnetic spectrum energy generally as it originates from the IRFS.

FIG. 5 is a view of the XY interface area of electromagnetic spectrum energy generally as it originates from the IRFS.

FIG. 6 is a symbol of the elements of the circuit FIGS. 2, 3 and 5 for ease of identification of the XY interface area of electromagnetic spectrum energy generally, as such designated area originates as a part of the IRFS and relates to the position of the SCE.

FIG. 7 is a symbol of the elements of the circuit FIGS. 2, 3 and 5 for ease of identification of the XY interface area of electromagnetic spectrum energy generally, as such designated area originates as a part of the IRFS and relates to the position of the SCE.

FIG. 8 is a symbol of the elements of the circuit FIGS. 2, 3 and 5 for ease of identification of the XY interface area of electromagnetic spectrum energy generally, as such designated area originates as a part of the IRFS and relates to the position of the SCE.

FIG. 9 shows a perspective view of the IRFS encapsulated with metal arches stretching around the IRFS with the two ends of each arch attaches to the electric pole of the IRFS, where a single inductor is in proximity to the IRFS.

FIG. 10 an axial end wise view of FIG. 9 showing arches as radiating lines from the center axis, said axis being the end wise view of the three mmic gain blocks depicted in FIG. 9.

FIG. 11 top cutaway view showing three encapsulating walls surrounding the IRFS and inductors terminating in proximity to the IRFS XY area generally, where each inductor has a B&C connector for connection to B&C cable input and output coaxial cables. Further is the illustration of a hollow tube with a symbol of a square with circle crossed in it depicting a valve for communicating noble gases, vacuum or pressure or dielectric liquids to enter, where such valve in the closed position can permanently maintain the interior area environment of XY such inserted “states of matter” permanently.

FIG. 12 Three dimensional cutaway of SCE with perspective of positioning of the IRFS, having disposed at positions around the IRFS inductor presenting a proximity of their center conductor to the area of the IRFS XY area generally.

FIG. 13 top cutaway view of FIGS. 14 and 15, such that the depiction is considered a rotation of the invention wherein FIGS. 14 and 15 it is rotated on a horizontal axis ninety degrees for purposes of fully illustrating the position of the IRFS as it relates to the SCE.

FIG. 14 cutaway view of said encapsulating walls FIG. 13 composed of optionally chosen MS and EMBED structure materials, are shown as to their position only in part where they are mere line drawings in positions to allow review of the internal structure of the IRFS in relation to the SCE.

FIG. 15 cutaway view of said encapsulating walls FIGS. 16 and 24 composed of optionally chosen MS and EMBED structure materials, are shown as to their position only in part where they are mere line drawings in positions to allow review of the internal structure of the IRFS in relation to the SCE

FIG. 16 top cutaway view of the IRFS within the SCE showing such interrelationship of positions so that FIG. 21 representing solder leads for PC board mounting can be best observed. As well illustrating the use of glue solder or a cork like plug to contain optionally chosen MS and EMBED structure materials within the interior wall or walls of the SCE, making such introduced material remain permanently within the SCE and around the IRFS.

FIG. 17 a horizontal axis rotation of FIG. 16 ninety degrees for the benefit of review to comprehend the SCE enclosure as it relates to soler land connectors from eh exterior of the SCE.

FIG. 18 a perspective view of the SCE module Integrated circuit exterior for the benefit of review to comprehend the SCE enclosure as it relates to soler land connectors from eh exterior of the SCE.

### DETAILED DESCRIPTION OF ILLUSTRATIVE EMBODIMENTS OF THE PRESENT INVENTION

A symbiotic amalgam package intrinsically interacting with patent application number 11758760 electromagnetic circuit. Such package is comprised of one or more layers of materials moderating the circuits electromagnetic field within. Such a package has proximal inductors that are electromagnetic conduits for input and output of electromagnetic energy terminating proximally in relation to the circuit within, where the inductors have moderation effects upon the electromagnetic frequency spectrum field of the circuit within. Such a moderating package has materials of optional composition and states of matter encapsulating proximal inductors terminating in proximity to the circuit within. The inductors both affect and are affected by the circuits electromagnetic frequency spectrum. Such inductors and circuits fields interact as symbiotic moderators each others electromagnetic frequency spectrum fields for balancing and or other functions as necessary.

Such moderation of the field proximal to the circuit designated here generally as XY, is by pressurized gases, partial vacuum and members of various materials that can generally be termed to be to suppress or enhance the XY field; for maintenance of intrinsic desired qualities of the XY field itself.

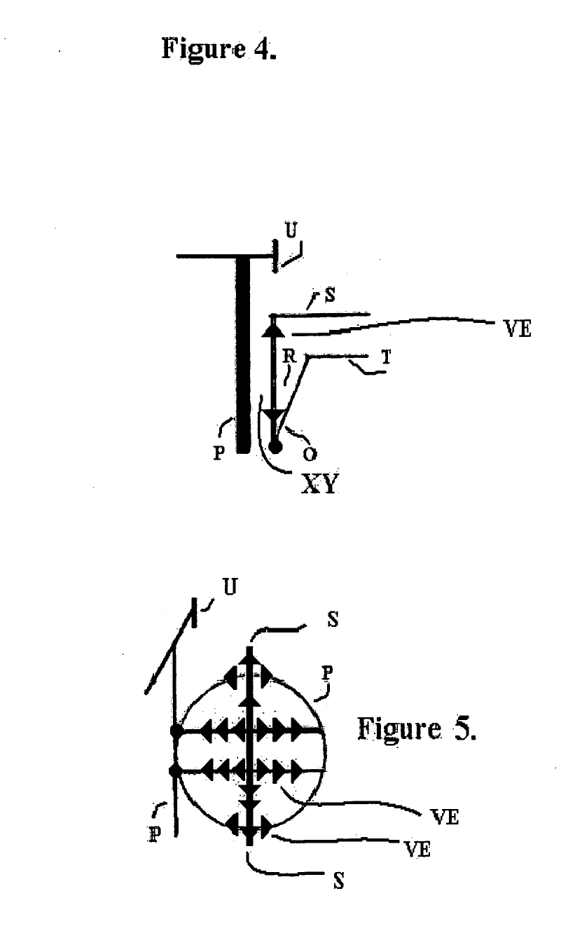

The IRFS circuit has a radio frequency field, designated the XY interacting field position being generally noted as (FIG. 4—N, O, P, Q, R); where that XY field reacts in symbiosis with adjacent immediately surrounding areas by induction of attendant radio frequency components of electric and magnetic fields; where such reactivity does occur in the immediate vicinity of XY, it can be of advantage to moderate such an areas capacitance, inductance, conductance and reflection of electromagnetic spectrum energy from XY by the encapsulating enclosure.

Suitable moderation of the symbiotic interaction between the IRFS and the surrounding area of the XY interacting field position being (FIG. 4—N, O, P, Q, R) is accomplished by the positing a partial vacuum or pressurized or non pressurized noble gases and or reactive gases and or conductors and or insulators and or electrets and or ferrite and or metamaterials and or multiple layers of any of the same previously mentioned types of materials. Heretofore known as moderating structures of MS structures.

Further moderation for containment of capacitance, inductance, conductance and reflection of electromagnetic spectrum energy from XY, include the application upon any and all such structures contrived; such MS structures are conductors and or insulators and or electrets and or ferrite and or metamaterials and or multiple layers of any of the same previously mentioned types of materials, where those structures can be coated or impregnated by one or more combinations of nanophase nanopowders, nanoparticles, nanocrystals and nano polymeric micro and nanoparticles and oriented and random magnetic nanoparticles; into layers around the IRFS. Such materials may also be layered combinations of aforesaid materials in isolated island like positions around the IRFS XY field. Heretofore such coatings or impregnation of particles into or on MS structures are to be known as EMBEDS.

The orientation of gases and or materials surrounding the IRFS circuit exist to modify the field emanating from XY and also from the IRFS. The container around IRFS is comprised of a single or multiple wall container not unlike a Faraday cage, where if there were three layers of Faraday cage enclosures the first of such an arrangement of enclosures would be the first to encapsulate the IRFS circuit and can have the open space within that container modified by inclusion within it of gases or partial vacuum for purpose of modifying the field XY as it relates to its impingement upon its immediate encapsulating environment.

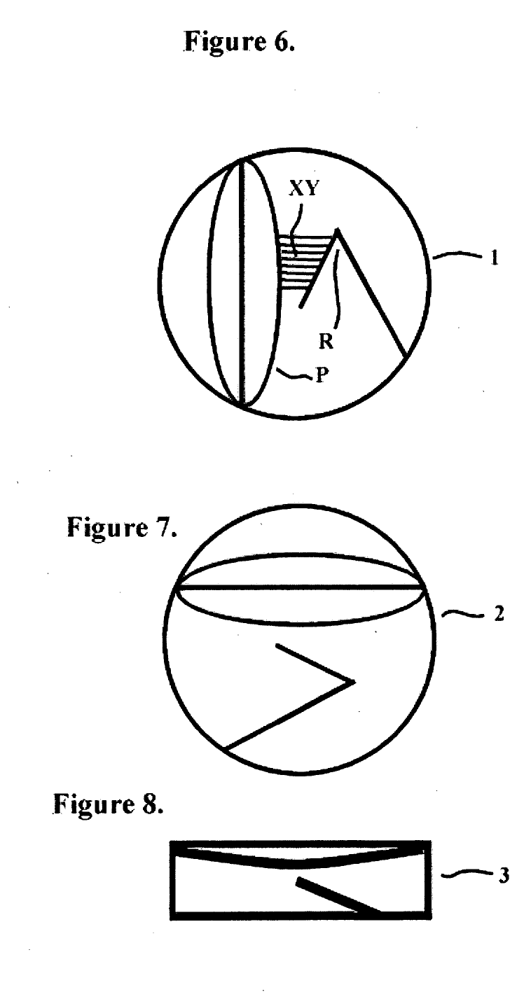

The diagrams of FIGS. 6 through 18 show the relationship of the encapsulation container to the IRFS circuit. Where the individual elements are shown where they are shown how they are generally posited one from another for the purpose of moderation of the XY. Such moderation of field XY by the gases, partial vacuum and members of various materials can generally be termed to be to suppress or enhance the XY field for intrinsic quality of the XY field itself.

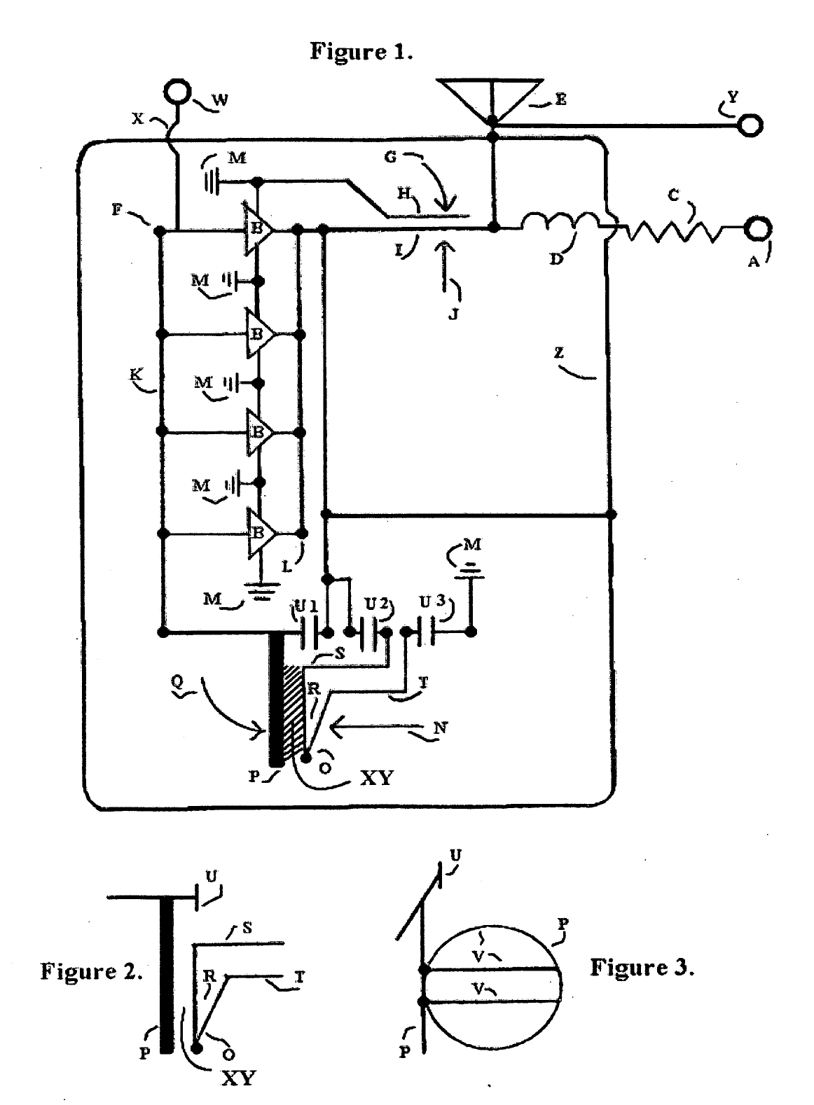

The IRFS drawings FIGS. 1,2 and 3 have (FIGS. 2 and 3) further defined. Letters U1, U2, and U3 are inductors or capacitors of “primary oscillation inductor or capacitor leg” and the “secondary oscillation inductor or capacitor leg”. Where shaded area XY is the “perpendicular oblique intersection point” exists between the “primary oscillation inductor or capacitor leg” referenced as P and “secondary oscillation inductor or capacitor leg” referenced as O. Letter R is the vee shaped area between the “secondary oscillation inductor or capacitor leg's” and is comprised of one inductor capacitor leg from both; is both a function is for stability where the two legs from it being S and T known as a single entity are known as O are double conductors perpendicularly presented in proximity to “secondary oscillation inductor or capacitor leg” referenced as P. Fewer or more “primary oscillation inductor or capacitor leg” and the “secondary oscillation inductor or capacitor leg”sections may be used without departing from the scope and spirit of the invention.

Modifications by way of miniaturization and or use of nano sized objects or materials including meta-materials are understood to be within the understanding of how the organization and means of relationship towards construction of the IRFS circuit without departing from the scope and spirit of the invention, where such alternate fabrication technologies intersect with the principle of the neutral state to support an interaction of supra oscillation from that that “perpendicular oblique intersection point” V, R, shaded area XY of fields where inductive and or capacitive members are inducting each other have separately and individually being the relative issue of the “right hand rule” where such electric current and magnetic field defined by that rule, have that fundamental rule active in both directions on each of the members of the intersection of the “perpendicular oblique intersection point”; where at that intersection those fields brought by proximity to intersect neutralize the cumulative support of each of the separate inductors at the intersection of the “perpendicular oblique intersection point” where such neutralized magnetic and electric fields (including current drift inside and on the surface of those conductors) to simultaneously attract and repel as a secondary reaction right hand rule oscillation reverberating away from and over the neural point through induction at the point of intersection; such portion of the circuit described as being s the “primary oscillation inductor or capacitor leg” and “secondary oscillation inductor or capacitor leg”. Where shaded area XY is the “perpendicular oblique intersection point” exists between the “primary oscillation inductor or capacitor leg” referenced as P and “secondary oscillation inductor or capacitor leg” referenced as O. As supported by a circuit for gain of transistor, monolithic microwave integrated circuit of preference a Cascadable Silicon Bipolar MMIC Amplifier or generally any gain block or device. Furthermore the scope and spirit of the invention will e understood to reduce the invention to solid state where air space inductor spaces are replaced by capacitors.

Letters referenced by V are the oblique ninety degree point of intersections of magnetic and electric constituents being conductors attached to P the “primary oscillation inductor or capacitor leg”. These conductors V designation points being proximally and generally ninety degrees in relation from R and O, are then in proximity for induction and or capacitance where shaded area XY designated a virtual axis between V and R as then shaded area XY is the intersection of biased in a relative neutral state from supporting each others oscillation due to the magnetic and electric fields; where such neutralized magnetic and electric fields (including current drift inside and on the surface of those conductors) to simultaneously attract and repel as a secondary reaction right hand rule oscillation reverberating away from and over the neural point through induction at the point of intersection. Shaded area XY can alternatively be a solid dielectric as is needed.

Letter N and Q delineated as arrows expresses the intention or capability to alter the distance between O and P for tuning and stability of the the intersection of the region axis intersection shaded area XY used to bias a relative neutral state to simultaneously attract and repel as a secondary reaction right hand rule oscillation reverberating away from and over the neural points on conductors V and O intersection being shaded area XY generally, through induction at their point of intersection again the region of field interaction shaded area XY. The following drawings FIGS. 1, 2, 3, 4 and 5 give an overall perspective of one of the embodiments of the invention originating from application 11758760 of which this innovation is a continuation-in-part. Where FIG. 1 is the IRFS of said application and the FIGS. 1 and 2 are detail of the elements that cause the XY field area emitter of electromagnetic frequency spectrum energy of the IRFS circuit. Further details as are desired to derive are within application 11758760.

Drawing 4 is of the same elements as drawing number 2 from a different view where the added feature is letters VE represented by arrows denoting the direction that electric and magnetic reflections occur away from the central portion of the length of inductor S.

Drawing 5 is of the same elements as drawing number 3 from a different view where the added feature is letters VE represented by arrows denoting the direction that electric and magnetic reflections occur away from the central portion of the length of inductor S in the background behind inductor P and V. Where on P and V the arrows show the electric and magnetic fields reflecting away from the inductor S being perpendicular to inductor V's and P at points adjacent to the intersection of S.

FIGS. 6, 7 and 8 are shown as symbols for simplicity in the further drawings where they each represent the area of FIG. 4—N, O, P, Q, R being the XY field generating elements. This symbol although not as detailed as FIGS. 2 and 3 in the original application USPTO application 11758760. Wherever observed by the reader are to be considered virtual block diagrams of the position of the FIG. 4—N, O, P, Q, R being the XY field generating elements. FIG. 3 is rectangular as opposed to the previous drawings 2 and 3, however there are parallel nuances of an arc and arrow like projections inside the rectangle similar generally to FIGS. 6 and 7 for the reader to take into account as one interprets the drawings. Letter's XY denote the shaded area between letters P and R; where that area is the origin of the IRFS infinity field emission.

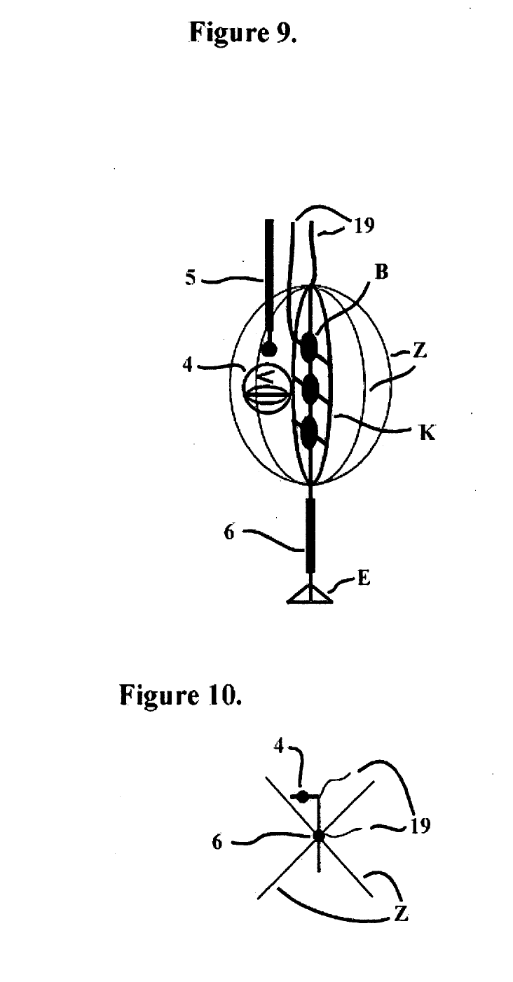

FIG. 9 is a perspective view of IRFS circuit drawing 1 of USPTO Application number 11758760. In the drawings FIG. 9 letter Z shows a series or arcs equivalent to the letter Z in FIG. 1; such arcs may be composed of any one or a combination of materials mentioned as MS structures that contribute to moderation of the field XY area. The letter B identifies an MMIC amplifier just as FIG. 1 illustrates, although for this drawing three MMIC's are shown. Letter K designates the same feature as FIG. 1 for general reader reference. Numeral 4 is the symbol for the general area of XY illustrated by FIG. 1 or 2. Numeral 5 is an inductor coaxial lead terminating in a proximal position to numeral 4, where its purpose of as for use as an input source bringing into the IRFS numeral 4 radio energy of various frequencies. Letter E is the symbol of an antenna radiator and is the same designation from FIG. 1 E, Numeral 6 is a coaxial lead from the IRFS to radiator E.

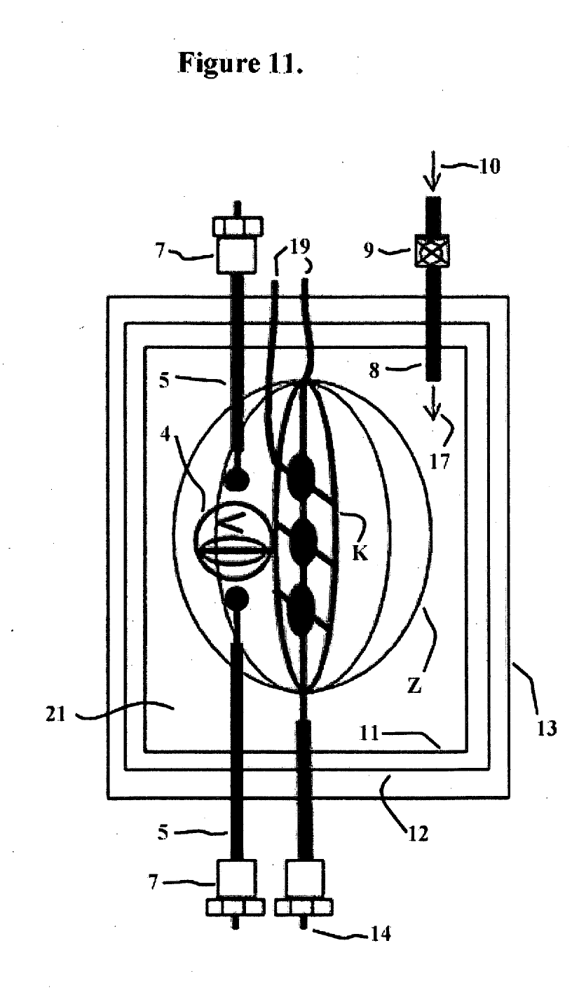

FIG. 10 is an axial view of drawing FIG. 9 where the numerals 4 is the structure of FIG. 4—N, O, P, Q, R and Z being the same designation as FIG. 9; where numeral 6 is the oblique ninety degree axial view through the coaxial lead 6.

FIG. 11 is a cross section view of the IRFS as shown from FIG. 9 with the addition of the IRFS circuit being enclosed by three enclosures indicate by numeral 11, 12 and 13. Such multiple container strategy in moderating the IRFS XY field may have one or more layers where only three are indicated be organized where they can be solid material without any space between them or can be hollow spaces for modification of the XY fields symbiotic relationship as it pertains to reactivity of the XY field. Such encapsulating containers may be composed of various materials as may be beneficial to the symbiotic relationship of the XY field and the containers which may be further modified to be EMBEDS types of materials. Numeral 5's show the contemplation of multiple inductors in proximity to the IRFS XY field generating area of FIG. 9-4 designated by symbol of FIG. 7-2. Numeral 21 is illustrative of the empty space that may have a partial vacuum or gases entering; where gases or vacuum numeral 10 are applied to tube numeral 8 to subsequently have such gases or partial vacuum 17 enter the inner container numeral 11 interior 21, where upon completion the tube numeral 8 is closed off where numeral 9 represents a valve block diagram symbol, Numerals 5 and 6 are coaxial leads communicating to the IRFS circuit, where numeral 7 shows a B&C connector with a center conductor visible as numeral 14.

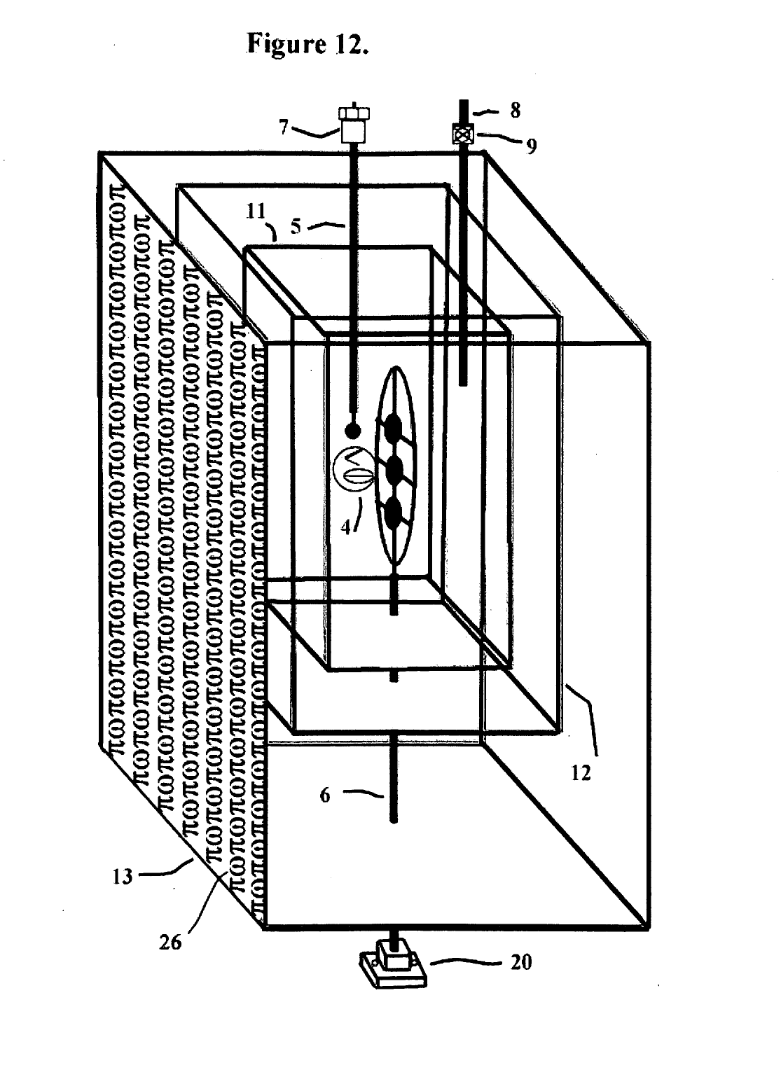

FIG. 12 is a partial cutaway perspective 3 dimensional view of the IRFS inside three successively encapsulating enclosures of numerals 11.12 and 13. Shown for the issue of demonstration of proximity of the various structural constituents as they are in relation one to another. The SCE encapsulating walls are shown as to their position only in part where they are mere line drawings in positions to allow review of the internal structure and as such the SCE walls are for issue of completeness the walls are intended as completely enclosing the IRFS; such line drawing is to provide perspective and the walls in a complete module are anticipated as composed of optionally chosen MS and EMBED structure materials, to completely encapsulate the IRFS where such walls are contiguous surrounding the IRFS barring feed through lines of power and inductors. The numerals 6,5,7,9.10,11,12 and 13 are as mentioned from previous drawings. The inner first and successive containers encapsulating container can be composed of any one or a combination of materials mentioned as MS structures for contributing to and affecting the electromagnetic field area generally designated XY. Numeral 20 is a traditional flanged microwave guide radiator connector for attachment as needs be to external instruments. Numeral 6 are coaxial conductors that pass through holes in the sides of the encapsulating walls to communicate between the IRFS circuit and the exterior of the outer container numeral 13, where such coaxial conductor and the holes through which they pass are a snug enough fit to mechanically support the IRFS without the need for additional accessory supports. Numeral 26 is noted to be Pi symbol and stylized W symbols representative as illustration of lithographed printing on the container 13 surface as a metamaterial element for moderation of IRFS circuits XY field; such lithograph of metamaterial shapes are to be understood to have first a layer of conductive material as ink lithographed upon the surface and then subsequently a lithographed layer covering of insulation paint or suitable material overlay the conductive metamaterial shapes, then the process of conductive symbols and overlapping of insulator material is continued as a multi layering of the metamaterial shapes until the desired moderation of IRFS circuit XY field is attained. The resultant culminates in a package suitable modular deployment of the system of IRFS/SCE interface to test equipment and incorporation into systems.

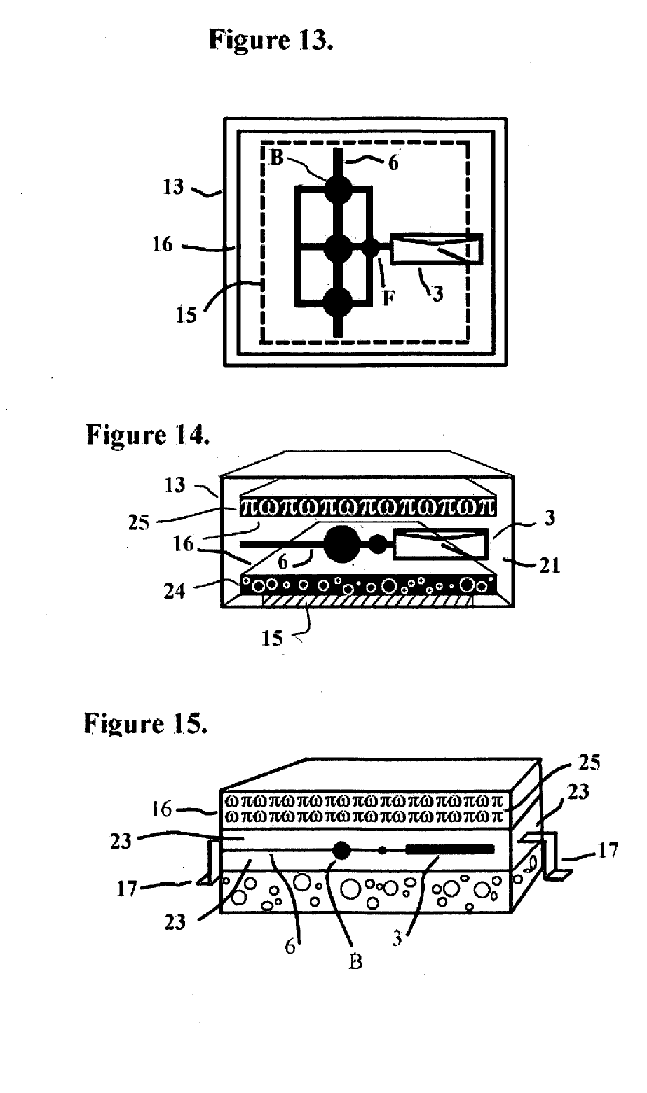

FIG. 13 is a cross section axial view of the IRFS circuit where is generally identical to FIG. 10 where the axial representation is relevant to the subsequent FIG. 14 showing the IRFS circuit rotated ninety degrees from the FIGS. 14 and 15 orientation; to illustrate the position of the IRFS within surrounding enclosure numeral 13. Numeral 16 is the a slab of MS structure which may have EMBED attributes, numeral 15 indicates a dotted line outlining a square area references an insulator that holds the MS structure and IRFS circuit free from the outer container numeral 13.

FIG. 14 is a sideways cross section view of the IRFS with the XY field representative of FIG. 4—N, O, P, Q, R designated as numeral 3 being a symbol FIG. 8-3 and F is an electronic connection from numeral 3 to the IRFS circuit. Numeral 21 represents the open area surrounding the IRFS circuit inside the container 13 for gases or partial vacuum. Other numerals shown are indicators that have been referenced from previous drawings. Numeral 16 represents slabs of MS structure which may have EMBED attributes, where slabs 16 are in proximity to the IRFS and XY radiating radio frequency field; such proximity creates between the XY field and the MS structure with or without EMBED properties a symbiotically dependent field between them. Numeral 16 as a slab of MS structure material where additional numeral 24 points also to that slab is noted to have circle symbols of varying diameter within 16 as illustrative addition that the circles show the EMBEDS particles entrained within slab 16 for moderation of IRFS circuits XY field. Numeral 16 as a slab of MS structure material where additional numeral 24 points also to that slab is noted to have Pi symbol and stylized W symbols present 16 as illustrative addition that the Pi symbol and stylized W symbols show metamaterial elements entrained within slab 16 for moderation of IRFS circuits XY field. The area designated as numeral 21 is optionally an fillable interior of encapsulating wall FIG. 13 by same hollow tube with valve means mentioned in FIG. 11 for introduction and communicating noble gases, vacuum or pressure or dielectric liquids inside, where such valve in the closed position can permanently maintain the interior area environment of XY such inserted “states of matter” permanently.

FIG. 15 is a sideways cross section view of the FIG. 14 where the IRFS circuit can be seen inside the enclosure numeral 13 composed of brass or conductive epoxy or other moldable material having additives of EMBEDS in and around the general position of the XY field as represented by symbol FIG. 8-3. Numeral 16's are rectangular slabs of MS structure material that may also have attributes of EMBED structures for subsequent additional contribution to and affecting of electromagnetic field area generally designated XY. Numeral 15 is an insulator holding the IRFS and its MS and EMBED structures within container 11 free and clear of the walls of container 11. Numeral 23 illustrates the space between the the IRFS where it is of a solid filler instead of empty space made of MS structure material and or combination with it having attributes of EMBED material qualities. The resultant culminates in a monolithic integrated circuit package suitable for surface or lead mounting on a PC board. Said walls to completely encapsulate the IRFS where they contiguously surround the IRFS creating an environmental area FIG. 21 composed of optionally chosen MS and EMBED structure materials.

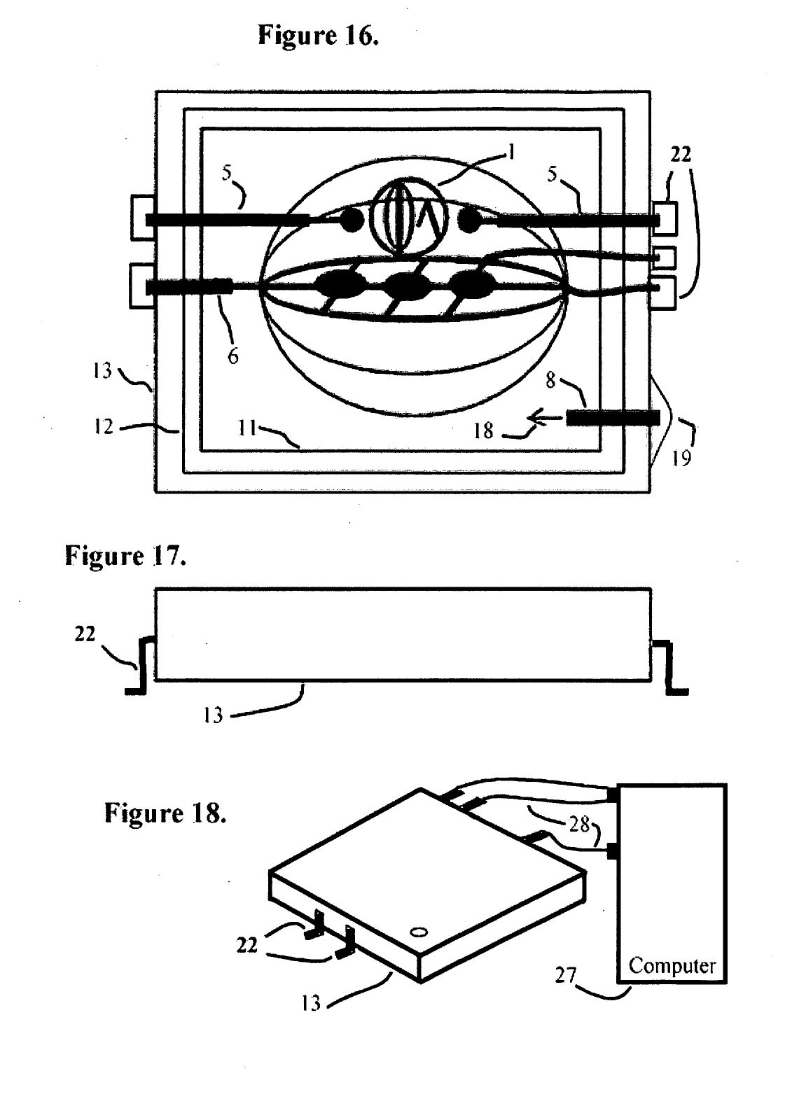

FIG. 16 shows an overhead cross section view the IRFS circuit within a plurality of encapsulating containers 11.12 and 13 with other numerals there for description of the various component structures, to be understood as taken from previous Figure's descriptions. Illustrated is the addition of a soldering wire land, for subsequent soldering of the IRFS circuit to a PC board is illustrated by numeral 22. Numeral 19 illustrates a plug, glue or solder capping off of the communication tube to the interior of the IRFS to prevent the escape of the IRFS optionally hollow. Interior's contents of a partial vacuum or gases.

In the drawings FIGS. 11,12 and 16 numeral 8 designates a permanent tube that can be closed after being used to communicate to the interior of the IRFS by using a cork like plug, spot glued or soldered shut as in FIG. 16 numeral 19 or have a valve numeral 9 for a conduit of the introduction of gas or vacuum into the interior of the IRFS circuit container; where such gas or partial vacuum can be composed of any one or a combination of gases mentioned, for contributing to moderating field XY.

FIG. 17 is a ninety degree rotation of the FIG. 16 where the IRFS outermost final enclosure is seen numeral 13 and the wire solder lead lands as numeral 22.

FIG. 18 is a perspective view of the IRFS packaged with outer container numeral being 13 and metal soldering leads are numeral's 22 shown. The resultant culminates in a monolithic integrated circuit package suitable for surface or lead mounting on a PC board. A computer FIG. 27 has cable leads 28 connected to SCE/IRFS Integrated Circuit illustrating the factual organization of such a construct; where the computer can be programmed to any output or input such of electromagnetic frequency energy such that it directly affects the IRFS through connections leads 28, such a computer connection is variously as need be connected to the power leads to affect such voltage and amperage and frequency.

While the invention herein disclosed has been described by means of specific embodiments, numerous modifications and variations could be made thereto by those skilled in the art without departing from the scope and spirit of the invention set forth in the claims.

What is claimed is:

1. By and through application number 11758760, titled “Infinite Radio Frequency Spectrum Transceiver”. A means of creating maintaining and moderating a symbiotic field between the IRFS circuit's XY field and the area surrounding that field, comprised of one or more containers. Where the innermost container has, depending upon the constituents used in said walls composition an inductive resonance that interacts with the XY field; with each successive container being inside the next successive container, all being intrinsic to moderating the field of XY. Where such means of moderation are for management of electromagnetic energy originating from the circuit emitters of the IRFS XY field; where proximal inductors become a part of the XY emitter field and cause as a result specific resonant feedback reactions to the XY intersection, having such feedback of resonant frequencies affect the XY field where they act together in symbiosis depending upon the input into such inductors and are as a result at time periods act as one inductor emitter.

2. Where claim 2 being based upon claim 1 in that the encapsulating containers as moderators of the XY field are also defined as island like slabs of material comprised of molecules of desired combinations as solids that affect radio energy emitted form the XY field of the IRFS circuit.

3. Where claim 3 being based upon claim 2 in that the area inside the encapsulating container walls and or between the island slab areas or elements within the container walls can be comprised of molecules of desired combinations as gases under pressure or partial vacuum that affect radio energy emitted form the XY field of the IRFS circuit.

4. Where claim 4 being based upon claim 3 in that the area surrounding the IRFS XY field can be comprised of an epoxy or other moldable material that is coated or has mixed into it EMBEDS material.

5. Where claim 5 being based upon claim 4 in that the EMBEDS can have embedded within then metamaterial shapes of desired character of such shapes and or have such shapes printed upon the EMBEDS or containers surrounding the circuit of the IRFS.

6. Where claim 6 being based upon claim 3 in that the container walls have throughputs for input and output of power supply and radio energy conduits as conductive leads; such throughputs and conduits communicate to the outside of the IRFS container for connection to appropriate exterior connection sources of power and input and output conductive leads to accessory equipment.

7. Where claim 5 being based upon claim 6 in that the throughputs and conduits conductor throughputs lead to the outside of the IRFS exterior for communication to output power mean of soldering leads, coaxial standard connectors and microwave radio waveguides.

8. An electromagnetic spectrum symbiotically reactive containment environment, between encapsulating packaging and an electronic circuit, as a package intrinsically linked by electromagnetic spectrum energy to said circuit comprising the steps of a means of creating a symbiotic field between the said said IRFS circuit's XY field and the area surrounding that field, comprised of one or more containers; with each successive container being inside the next successive container, all being intrinsic to moderating the field of XY.

9. A first position of a three dimensional space comprised of at least one wall made of metal and or metallic and or MS and EMBED structure material of said space, extending completely around said circuit fully encapsulating said circuit portion, where said encapsulating walls can have itself encapsulated by one or more same said encapsulating walls, with each successively encapsulating wall being equidistant from all other encapsulating walls so as not to be touching each other, where each metallic encapsulation is touching the other successively encapsulating walls they are optionally coated with an insulator inside and out upon their surfaces;

10. Space adjacent to the electronic circuit and within first encapsulation envelope around said circuit having within such adjacent space filled with MS and EMBED structure material and or noble gases and or vacuum or pressurized;

11. One or more pluralities of encapsulating envelopes of said circuit having two or more coaxial leads with a center conductor for transferring input and output electromagnetic spectrum energy, said lead originating from the outside exterior of the outermost encapsulating wall, having upon such leads exterior termination a coaxial B&C connector, where such insulated coaxial throughput lead transverses to penetrate through said envelopes from the exterior of the outermost envelope and into and through subsequent and innermost interior encapsulating envelope wall, said insulated coaxial lead terminating within the environment space adjacent to the circuit, where the center conductor of said coaxial lead terminates as an electrode tip within said interior environment, where said coaxial electrode tip terminates within said area space filled with MS and EMBED structure material and or noble gases and or vacuum or pressurized, such that such coaxial leads tips are in proximity to said circuit; where said inductors can as needed be connected to a computerized input and output of electromagnetic spectrum energy for the processing and manipulation of the XY field for such purposes as are desired.

12. one or more metal arches in parallel or other formation running approximately parallel for encapsulating said circuit where one end of said arch surrounding said circuit originating from the electrical positive side of the circuit and the opposite side of such arches end terminating upon the furthest point from the first end upon the electrical positive position of said circuit, both ends of each arch optionally connected to electrical negative position of said circuit;

13. input and output means by communicating means of hollow tubular member originating from the exterior of the outermost encapsulating wall means around said circuit, where said hollow tubular member begins outside the outermost said encapsulating wall with a common mechanical valve for opening and closing said hollow tubular member which communicates to the interior environment area around said circuit by penetrating each and all encapsulating walls and terminating in the innermost environment adjacent to the said circuit, said mechanical valve means optionally is by soldering the tubular member or glue means at the exterior most opening outside the encapsulating walls for plugging the mouth of said tubular member as a permanent plug means;

14. Said coaxial leads electrode tips in proximity to said circuit, are encapsulated with the interior encapsulating wall means of coaxial tip terminations within said area space, said space filled with MS and EMBED structure material and or noble gases and or vacuum or pressurized, such that such coaxial leads tips are in proximity to said circuit, where electromagnetic spectrum energy from said circuit and said electrode tip are in proximity to each other affecting each others electromagnetic spectrum energy, where said environment of interior of innermost encapsulating wall space is filled with MS and EMBED structure material and or noble gases and or vacuum or pressurized and or dielectric liquids, where said coaxial leads tips are in proximity to said circuit, where such material surrounding said coaxial electrode tip and said circuit by said material encapsulating said electrode tips and said circuit thereby moderates the electromagnetic spectrum energy of said electrode tips and said circuit.
